(19) United States
(12) Patent Application Publication
(10) Pub. No.: US 2024/0170548 A1
(43) Pub. Date: May 23, 2024

(54) SEMICONDUCTOR DEVICE AND METHOD OF MANUFACTURING THE SAME

(71) Applicant: Renesas Electronics Corporation, Tokyo (JP)

(72) Inventor: Hiroya SHIMOYAMA, Tokyo (JP)

(21) Appl. No.: 18/515,187

(22) Filed: Nov. 20, 2023

(30) Foreign Application Priority Data
Nov. 21, 2022 (JP) 2022-185552

(51) Int. Cl. H01L 29/423; H01L 21/02; H01L 21/28; H01L 21/311; H01L 21/3213; H01L 29/40; H01L 29/49; H01L 29/51; H01L 29/66; H01L 29/78; H01L 29/788

(52) U.S. Cl. CPC H01L 29/42328; H01L 21/02164; H01L 21/0217; H01L 21/28035; H01L 21/31111; H01L 21/32133; H01L 29/401; H01L 29/402; H01L 29/4916; H01L 29/518; H01L 29/66484; H01L 29/66666; H01L 29/66825; H01L 29/7827; H01L 29/7831; H01L 29/7889

(57) ABSTRACT

Provided is a semiconductor device including a field plate electrode, a floating electrode, and a gate electrode and satisfying a relationship of T₁>T₂>T₃, where T₁ is a thickness of an insulating film between the field plate electrode and an N-type drift region, T₂ is a thickness of the insulating film between the floating electrode and the N-type drift region, and T₃ is a thickness of the insulating film between the gate electrode and a P-type channel region.

### CROSS-REFERENCE TO RELATED APPLICATIONS

The disclosure of Japanese Patent Application No. 2022-185552 filed on Nov. 21, 2022 including the specification, drawings and abstract is incorporated herein by reference in its entirety.

### BACKGROUND

The present disclosure relates to a semiconductor device and a method of manufacturing the same.

There is disclosed a technique listed below.
[Patent Document 1] Japanese Unexamined Patent Application Publication No. 2011-199109

Patent Document 1 describes an in-trench double-gate-type vertical power metal oxide semiconductor field effect transistor (MOSFET) having an intrinsic gate electrode and a buried field plate electrode in a trench. Patent Document 1 describes the in-trench double-gate-type power MOSFET in which a trench interval is 1.5 μm or less and 0.1 μm or more.

### SUMMARY

Currently, power MOSFETs having low to middle withstand voltages between 30 and 150 V generally adopt a vertical MOSFET structure in which an oxide film is formed inside a trench formed in a Si wafer and a gate electrode and a field plate electrode are provided on the inner side of the oxide film. An object of the field plate electrode is to generate a reduced surface field (RESURF) effect by applying a source potential.

In order to improve performance with this structure, it is particularly important to reduce a resistance of a conductive region of a drift region, and this has been handled by increasing a doping concentration of an epitaxially grown N-type semiconductor that forms the drift region. However, when the doping concentration is increased, the balance of an electric field is lost, and problems such as a decrease in the withstand voltage and an increase in temperature dependency occur. Therefore, it is difficult to improve the performance to a certain level or more.

Therefore, an object of the present disclosure is to provide a semiconductor device including a vertical MOSFET having improved performance without increasing a doping concentration of an N-type drift region.

Other problems and novel features will be apparent from description of the present specification and the attached drawings.

According to one embodiment, a semiconductor device includes a floating electrode between a field plate electrode and a gate electrode in an opening. When a thickness of an insulating film between the field plate electrode and an N-type drift region is T₁, a thickness of the insulating film between the floating electrode and the N-type drift region is T₂, and a thickness of the insulating film between the gate electrode and a P-type channel region is T₃, a relationship of T₁>T₂>T₃ is satisfied.

According to the embodiment, it is possible to provide the semiconductor device including the vertical MOSFET having improved performance without increasing the doping concentration of the N-type drift region.

### BRIEF DESCRIPTION OF THE DRAWINGS

FIG. 1 is a schematic view of a conventional vertical MOSFET and a vertical MOSFET according to a first embodiment.

FIG. 2 is a schematic enlarged view of the vertical MOSFET according to the first embodiment.

FIG. 3 is a view illustrating a relationship between a withstand voltage and an on-resistance when a thickness of a side wall insulating film of a floating electrode of the vertical MOSFET according to the embodiment is changed.

FIG. 4 is a view illustrating a potential distribution and a current density distribution in an on-state of the vertical MOSFET according to the first embodiment.

FIG. 5 is a view illustrating cross-sectional views and electric field intensities of a conventional structure and a structure of the present disclosure in an off-state.

FIG. 6 is a view illustrating the electric field intensities of the conventional structure and the structure of the present disclosure.

FIG. 7 is a view illustrating cross-sectional views and electrical characteristics of the conventional vertical MOSFET, the vertical MOSFET according to the first embodiment, and vertical MOSFETs according to first to third embodiments.

FIG. 8 is a view illustrating cross-sectional views and electrical characteristics of vertical MOSFETs according to fourth and fifth embodiments.

FIG. 9 is a view illustrating a method of manufacturing a vertical MOSFET according to an embodiment.

### DETAILED DESCRIPTION

### Embodiments

The following description and the drawings are omitted and simplified as appropriate to clarify the description. In the drawings, the same elements are denoted by the same reference numerals, and redundant description is omitted as necessary.

(Description of Vertical MOSFET According to First Embodiment)

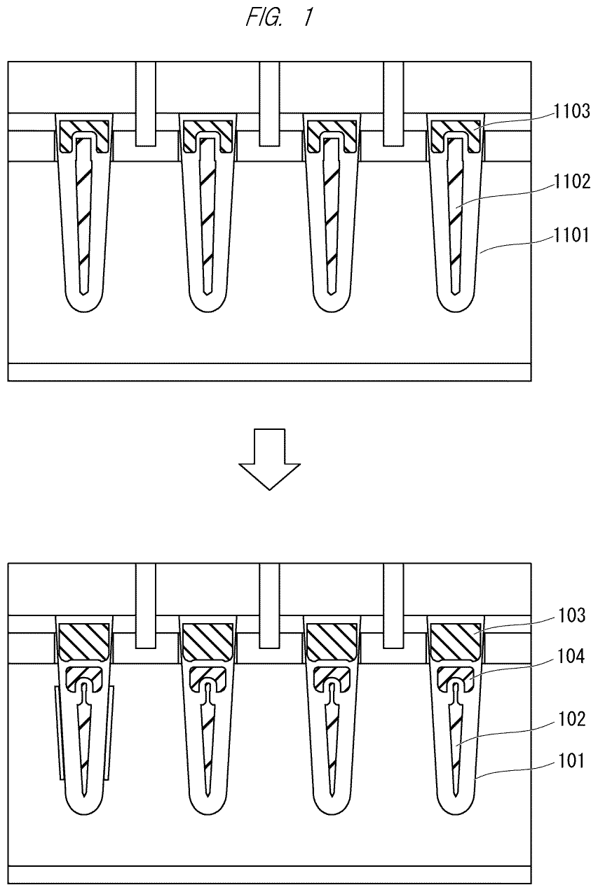

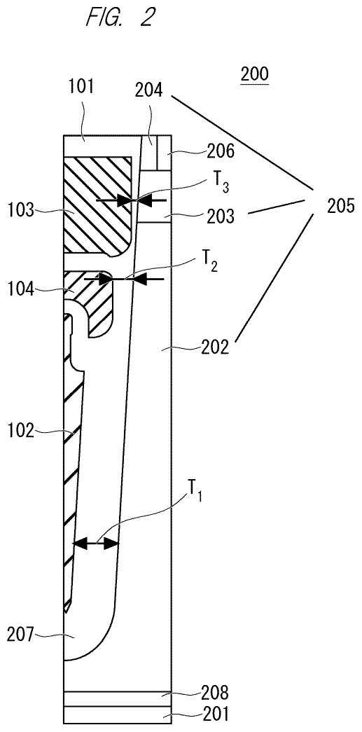

FIG. 1 is a schematic view of a conventional vertical MOSFET and a vertical MOSFET according to a first embodiment. FIG. 2 is a schematic enlarged view of the vertical MOSFET according to the first embodiment. The vertical MOSFET according to the first embodiment will be described with reference to FIGS. 1 and 2.

As illustrated in the upper view of FIG. 1, in a conventional structure, a field plate electrode 1102 and a gate electrode 1103 are buried in an opening 1101 which is a trench. When the field plate electrode 1102 is set to not only a source potential but also a gate potential, an electron accumulation layer is formed on a side wall of the trench in an on-state, and a resistance of a drift region can be reduced. In an off-state, the potential of the field plate electrode 1102 is 0 V, so that a withstand voltage can be made equivalent to that when the field plate electrode 1102 is set to the source potential.

When the potential of the field plate electrode 1102 is the gate potential, Crss, which is a capacitance between a gate and a drain, greatly increases. When Ciss/Crss decreases, malfunction such as self-turn-on easily occurs. Therefore, Crss is desirably as low as possible. As compared with the vertical MOSFET in which the field plate electrode 1102 is connected to the source potential, the vertical MOSFET in which the field plate electrode is connected to the gate potential has Ciss/Crss lowered by one order of magnitude, and thus, cannot exhibit sufficient superiority.

In this regard, a semiconductor device has been developed in which a gate electrode 103, a field plate electrode 102 connected to a source potential, and a floating electrode 104 whose potential is not fixed but is a floating potential are provided inside an opening 101 covered with an insulator formed on a Si substrate.

As illustrated in FIG. 2, a semiconductor device 200 according to the first embodiment includes a drain electrode 201, an N+ substrate 208 on the drain electrode 201, a semiconductor layer 205 on the N+ substrate 208, and a source contact electrode 206 on the semiconductor layer 205.

The semiconductor layer 205 includes an N-type drift region 202 on the N+ substrate 208, that is, on the drain electrode 201, a P-type channel region 203 on the N-type drift region 202, and an N-type source region 204 on the P-type channel region 203. The source contact electrode 206 in contact with the P-type channel region 203 and the N-type source region 204 is formed on the N-type source region 204.

The semiconductor device 200 further includes the opening 101 that is provided in the semiconductor layer 205 and extends from the N-type source region 204 to the N-type drift region 202. The field plate electrode 102, which is adjacent to the N-type drift region 202 with an insulating film 207 interposed therebetween and is connected to the source potential, is arranged in the opening 101. The gate electrode 103, adjacent to the P-type channel region 203 with the insulating film 207 interposed therebetween, is further arranged in the opening 101. The floating electrode 104 adjacent to the N-type drift region 202 between the N-type drift region 202, adjacent to the field plate electrode 102, and the P-type channel region 203 with the insulating film 207 interposed therebetween is further arranged in the opening 101.

The semiconductor device 200 according to the first embodiment has a shape in which the field plate electrode 102 slightly enters a recess of the floating electrode 104.

Here, when a thickness of the insulating film 207 between the field plate electrode 102 and the N-type drift region 202 is T₁, a thickness of the insulating film 207 between the floating electrode 104 and the N-type drift region 202 is T₂, and a thickness of the insulating film 207 between the gate electrode 103 and the P-type channel region 203 is T₃, the semiconductor device 200 satisfies a relationship of T₁>T₂>T₃.

(Description of Simulation of Vertical MOSFET According to First Embodiment)

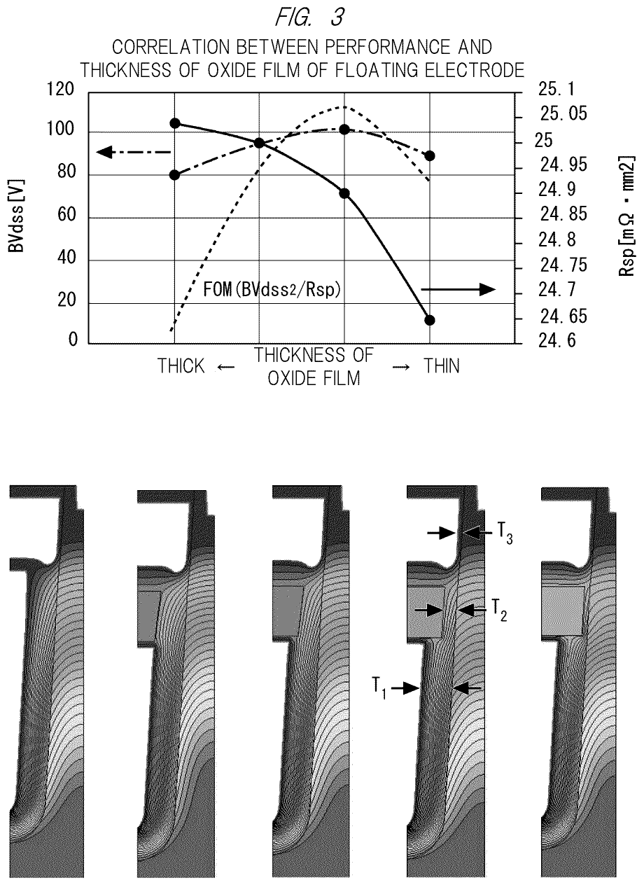

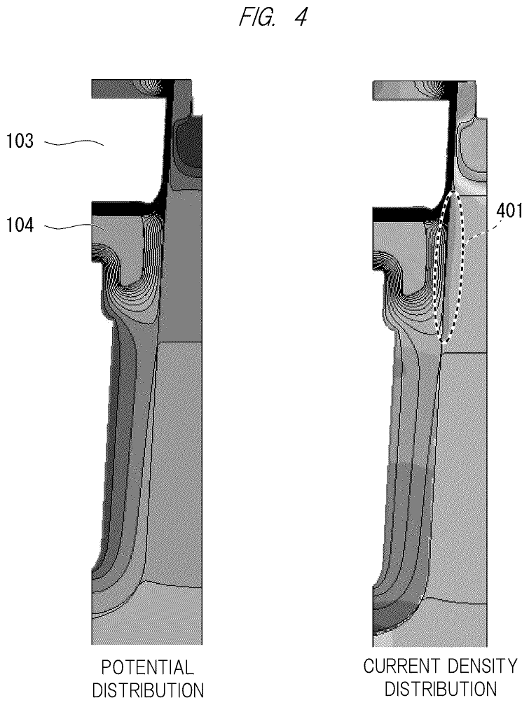

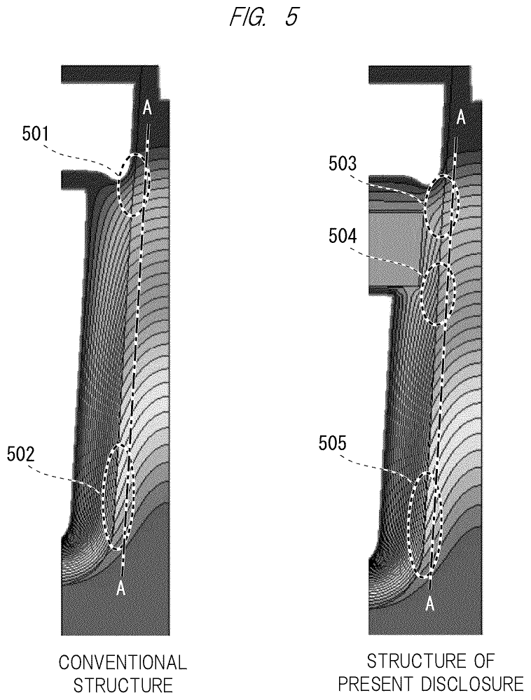

FIG. 3 is a view illustrating a relationship between a withstand voltage and an on-resistance when a thickness of a side wall insulating film of the floating electrode of the vertical MOSFET according to the embodiment is changed. FIG. 4 is a view illustrating a potential distribution and a current density distribution in the on-state of the vertical MOSFET according to the first embodiment. FIG. 5 is a view illustrating cross-sectional views and electric field intensities of the conventional structure and the structure of the present disclosure in the off-state. A simulation of the vertical MOSFET according to the embodiment will be described with reference to FIGS. 3 to 5.

As illustrated in the lower view of FIG. 3, changes in Rsp, which is the on-resistance, and BVdss, which is the withstand voltage, due to the thickness of the insulating film 207 between the floating electrode 104 and the N-type drift region 202 were simulated.

In the second structure from the left in which the thickness of the insulating film 207 between the floating electrode 104 and the N-type drift region 202 is the thickest, Rsp decreased, but BVdss decreased as compared with the conventional structure at the leftmost end. Next, in the second structure from the right in which the relationship of the insulating film 207 satisfies T₁>T₂>T₃, Rsp decreased, and BVdss increased. In a structure at the right end in which values of T₂ and T₃ are close, Rsp decreased, but BVdss decreased.

As illustrated in the upper view of FIG. 3, there is a correlation between the thickness of the insulating film 207 of the floating electrode 104 and transistor performance. As indicated by FOM (BVdss²/Rsp), the withstand voltage is improved while the on-resistance decreases when the thickness of the insulating film 207 satisfies T₁>T₂>T₃. That is, when the thickness of the insulating film 207 satisfies T₁>T₂>T₃, an on-current increases, and the withstand voltage is improved.

A mechanism for improving the on-resistance in the on-state will be described. As illustrated in FIG. 4, the potential of the floating electrode 104 rises due to capacitive junction with the gate electrode 103 in the on-state. When the potential of the floating electrode 104 becomes a positive potential, an electron accumulation layer 401 is formed on a side wall of the floating electrode 104. This effect improves an electric resistance of the N-type drift region 202.

A mechanism for improving the withstand voltage in the off-state will be described. As illustrated in the left view of FIG. 5, in the conventional vertical MOSFET, the electric field intensity is high in an opening bottom portion 502 and a vicinity 501 of the gate electrode, but the electric field intensity is low in a region therebetween. On the other hand, as illustrated in the right view of FIG. 5, in the structure of the present disclosure, the electric field intensity is high not only in an opening bottom portion 505 and a vicinity 503 of the gate electrode but also in a vicinity 504 of the floating electrode.

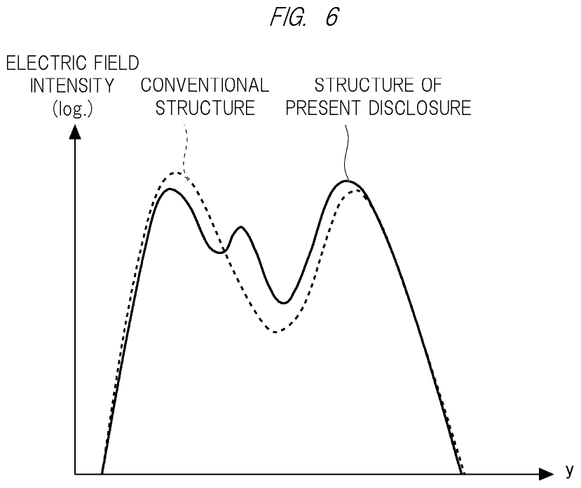

In the conventional structure, a curve having two peaks indicated by a dotted line in FIG. 6 is drawn in a cross section taken along line A-A of the left view in FIG. 5. On the other hand, in the structure of the present disclosure, a curve having three peaks indicated by a solid line in FIG. 6 is drawn in a cross section taken along line A-A of the right view in FIG. 5. An area surrounded by the curve in FIG. 6 indicates the withstand voltage. It can be seen that the structure of the present disclosure having the three peaks has a larger area and a more excellent withstand voltage as compared with the conventional structure having the two peaks.

(Comparison Between Conventional Vertical MOSFET and Vertical MOSFETs According to First to Third Embodiments)

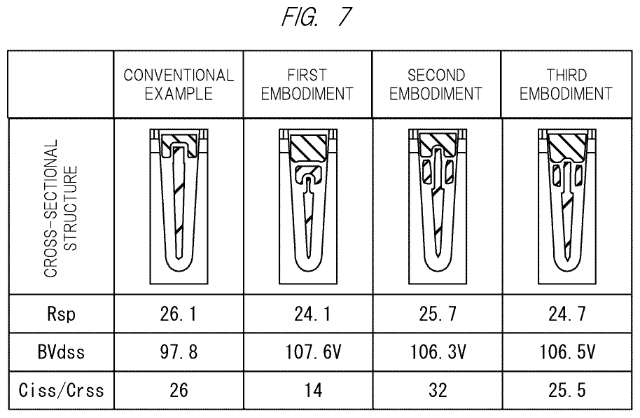

FIG. 7 is a view illustrating cross-sectional views and electrical characteristics of the conventional vertical MOSFET, the vertical MOSFET according to the first embodiment, and vertical MOSFETs according to first to third embodiments. The conventional vertical MOSFET and the vertical MOSFETs according to the first to third embodiments will be compared with reference to FIG. 7.

In the vertical MOSFET according to the second embodiment, the floating electrode 104 is arranged around the field plate electrode 102 as compared with the vertical MOSFET according to the first embodiment. Further, in the vertical MOSFET according to the second embodiment, the field plate electrode 102 penetrates the floating electrode 104 and protrudes into a recess of the gate electrode 103.

In the vertical MOSFET according to the third embodiment, the floating electrode 104 is arranged around the field plate electrode 102 as compared with the vertical MOSFET according to the first embodiment. Further, in the vertical MOSFET according to the third embodiment, the field plate electrode 102 has a shape of penetrating the floating electrode 104 and stopping without protruding into the recess of the gate electrode 103.

In each of the vertical MOSFETs of the first to third embodiments, Rsp, which is the on-resistance, decreases, and BVdss, which is the withstand voltage, increases as compared with the conventional vertical MOSFET. When the floating electrode enters between the gate electrode and the field plate electrode, it is possible to provide a semiconductor device with an increased on-current and an improved withstand voltage.

In particular, it can be seen that Ciss/Crss increases so that malfunction such as self-turn-on hardly occurs in the second and third embodiments. Therefore, when the floating electrode enters between the gate electrode and the field plate electrode, the field plate electrode penetrates the floating electrode, it is possible to provide a semiconductor device with an increased on-current, an improved withstand voltage, and a low possibility of malfunction.

(Comparison Between Conventional Vertical MOSFET and Vertical MOSFETs According to Fourth and Fifth Embodiments)

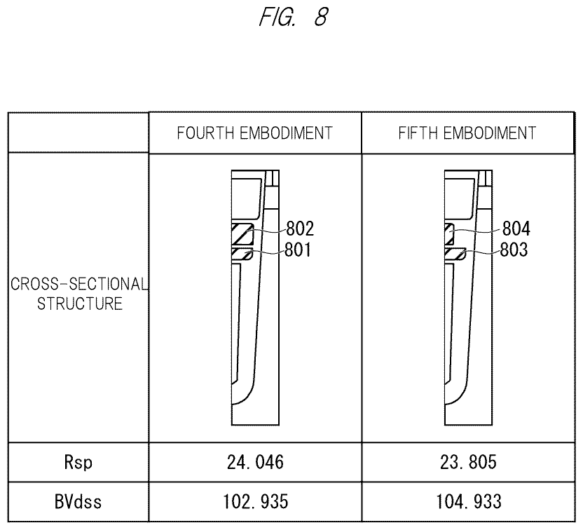

FIG. 8 is a view illustrating cross-sectional views and electrical characteristics of vertical MOSFETs according to fourth and fifth embodiments. The conventional vertical MOSFET and the vertical MOSFETs according to the fourth and fifth embodiments will be compared with reference to FIG. 8.

The fourth and fifth embodiments have a structure in which the floating electrode 104 is divided into a plurality of floating electrodes. In the fourth embodiment, a floating and a floating electrode 801 electrode 802 satisfy the relationship of T₁>T₂>T₃. In the fifth embodiment, a floating electrode 803 satisfies the relationship of T₁>T₂>T₃.

In both cases, the on-resistance decreases and the withstand voltage is improved as compared with the conventional vertical MOSFET illustrated in FIG. 7. Therefore, it can be seen that a semiconductor device with an increased on-current and an improved withstand voltage can be provided when any of the floating electrodes satisfies the relationship of T₁>T₂>T₃ even if the floating electrode 104 is divided into the plurality of floating electrodes.

(Description of Method of Manufacturing Vertical MOSFET According to Embodiment)

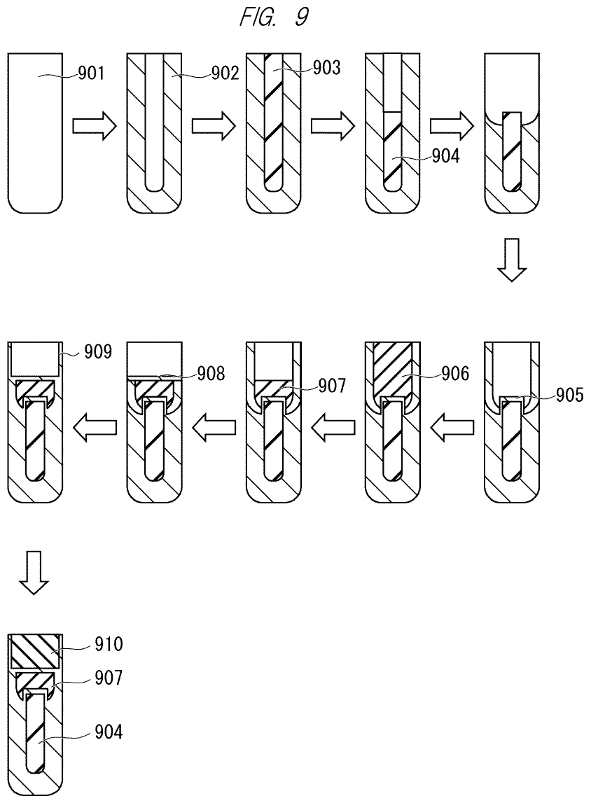

FIG. 9 is a view illustrating a method of manufacturing a vertical MOSFET according to an embodiment. The method of manufacturing a vertical MOSFET according to the embodiment will be described with reference to FIG. 9.

First, the N-type drift region 202 is formed on the N+ substrate 208 although not illustrated. Next, an opening 901 is formed in the N-type drift region 202 as illustrated in the upper left view of FIG. 9. Next, a first insulating film 902 is formed in the opening 901 as illustrated in the second view from the left among the upper views of FIG. 9. The first insulating film 902 may be a silicon oxide film or a silicon nitride film. The first insulating film 902 preferably includes a silicon oxide film.

Next, a first conductor 903 is buried in the first insulating film 902 as illustrated in the middle of the upper views of FIG. 9. The first conductor 903 can be formed using N-type polysilicon, P-type polysilicon, a metal material, or the like. Next, the first conductor 903 is etched to form a field plate electrode 904 as illustrated in the second view from the right among the upper views of FIG. 9. The field plate electrode 904 is adjacent to the N-type drift region 202 with the first insulating film 902 interposed therebetween.

Next, the first insulating film 902 as is etched illustrated in the upper right view of FIG. 9. Next, a second insulating film 905 is formed on the first insulating film 902, the field plate electrode, and a side wall of the opening 901 as illustrated in the middle right view of FIG. 9. The second insulating film 905 may be a silicon oxide film or a silicon nitride film. The second insulating film 905 preferably includes a silicon oxide film.

Next, a second conductor 906 is formed on the second insulating film 905 as illustrated in the second view from the right among the middle views of FIG. 9. The second conductor 906 can be formed using N-type polysilicon, P-type polysilicon, a metal material, or the like. Next, the second conductor 906 is etched to form a floating electrode 907 as illustrated in the middle of the middle vies of FIG. 9. The floating electrode 907 is adjacent to the N-type drift region 202 with the second insulating film 905 interposed therebetween.

Next, the second insulating film 905 is etched to form a third insulating film 908 on the second insulating film 905 and the floating electrode 907, and the third insulating film 908 is etched as illustrated in the second view from the left among the middle views of FIG. 9. The third insulating film 908 may be a silicon oxide film or a silicon nitride film. The third insulating film 908 preferably includes a silicon oxide film.

Next, a fourth insulating film 909 is formed on the third insulating film 908 and a side wall of the opening 901 as illustrated in the middle left view of FIG. 9. The fourth insulating film 909 may be a silicon oxide film or a silicon nitride film. The fourth insulating film 909 preferably includes a silicon oxide film. In particular, the fourth insulating film 909 is preferably a thermal oxide film.

As illustrated in the lower view of FIG. 9, a gate electrode 910 is formed on the fourth insulating film 909. The gate electrode 910 can be formed using N-type polysilicon, P-type polysilicon, a metal material, or the like.

Although not illustrated, ion implantation is performed on the N-type drift region 202 to form the P-type channel region 203 on the N-type drift region 202 and the N-type source region 204 on the P-type channel region 203. The P-type channel region 203 is formed in a region where the gate electrode 910 is adjacent with the fourth insulating film 909 interposed therebetween. Further, the N-type source region 204 is formed in a region where a part of the gate electrode 910 is adjacent with the fourth insulating film 909 interposed therebetween. Here, a region formed by the N-type drift region 202, the P-type channel region 203, and the N-type source region 204 is referred to as the semiconductor layer 205.

Finally, although not illustrated, the source contact electrode 206 in contact with the P-type channel region 203 and the N-type source region 204 is formed on the N-type source region 204, and the drain electrode 201 is formed under the semiconductor layer 205.

The vertical MOSFET satisfies a relationship of T₁>T₂>T₃, where T₁ is a thickness of the first insulating film 902, T₂ is a thickness of the second insulating film 905, and T₃ is a thickness of the fourth insulating film 909.

For example, a semiconductor device according to the above-described embodiment may have a configuration in which a conductivity type (a p type or an n type) of a semiconductor substrate, a semiconductor layer, a diffusion layer (diffusion region), or the like is inverted. Therefore, when one conductivity type of the n type and the p type is a first conductivity type and the other conductivity type is a second conductivity type, it is possible to set the first conductivity type as the p type and the second conductivity type as the n type, and conversely, it is also possible to set the first conductivity type as the n type and the second conductivity type as the p type.

As above, the invention that has been made by the inventor has been described in detail based on the embodiments, the invention is not limited to the above-described embodiments, and it is obvious that various types of modifications can be made in the range of not departing from a gist thereof.

What is claimed is:

1. A semiconductor device comprising:
a drain electrode;
a semiconductor layer including an N-type drift region on the drain electrode, a P-type channel region on the N-type drift region, and an N-type source region on the P-type channel region;
a source contact electrode on the N-type source region;
an opening provided in the semiconductor layer, the opening extending from the N-type source region to the N-type drift region;
a field plate electrode that is adjacent to the N-type drift region arranged in the opening with an insulating film interposed between the field plate electrode and the N-type drift region and is connected to a source potential;
a gate electrode adjacent to the P-type channel region arranged in the opening with the insulating film interposed between the gate electrode and the P-type channel region; and
a floating electrode adjacent to an N-type drift region between the N-type drift region adjacent to the field plate electrode arranged in the opening and the P-type channel region with the insulating film interposed between the floating electrode and the N-type drift region,
wherein, when a thickness of the insulating film between the field plate electrode and the N-type drift region is T₁, a thickness of the insulating film between the floating electrode and the N-type drift region is T₂, and a thickness of the insulating film between the gate electrode and the P-type channel region is T₃, a relationship of T₁>T₂>T₃ is satisfied.

2. The semiconductor device according to claim 1,
wherein the floating electrode is provided around the field plate electrode.

3. The semiconductor device according to claim 2,
wherein the field plate electrode penetrates the floating electrode and is adjacent to the gate electrode.

4. The semiconductor device according to claim 1,
wherein the insulating film contains silicon oxide.

5. The semiconductor device according to claim 1,
wherein the insulating film contains silicon nitride.

6. The semiconductor device according to claim 1,
wherein the floating electrode is divided into a plurality of floating electrodes, and at least one of the plurality of floating electrodes satisfies a relationship of T₁>T₂>T₃, where T₂ is a thickness of the insulating film between the one floating electrode and the N-type drift region.

7. The semiconductor device according to claim 1,
wherein the gate electrode, the floating electrode, and the field plate electrode contain N-type polysilicon.

8. The semiconductor device according to claim 1,
wherein the gate electrode, the floating electrode, and the field plate electrode contain P-type polysilicon or a metal material.

9. A method of manufacturing a semiconductor device comprising:
forming a drain electrode;
forming a semiconductor layer including an N-type drift region on the drain electrode, a P-type channel region on the N-type drift region, and an N-type source region on the P-type channel region;
forming an opening from the N-type source region to the N-type drift region in the semiconductor layer;
forming a first insulating film in the opening;
forming a first conductor on the first insulating film;
etching the first conductor to form a field plate electrode adjacent to the N-type drift region with the first insulating film interposed between the field plate electrode and the N-type drift region;
etching the first insulating film;
forming a second insulating film on the first insulating film, the field plate electrode, and a side wall of the opening;
forming a second conductor on the second insulating film;
etching the second conductor to form a floating electrode adjacent to the N-type drift region with the second insulating film interposed between the floating electrode and the N-type drift region;
etching the second insulating film;
forming a third insulating film on the second insulating film and the floating electrode;
etching the third insulating film;
forming a fourth insulating film on the third insulating film and on a side wall of the opening; and
forming, on the fourth insulating film, a gate electrode adjacent to the P-type channel region with the fourth insulating film interposed between the gate electrode and the P-type channel region,
wherein, when a thickness of the first insulating film between the field plate electrode and the N-type drift region is T₁, a thickness of the second insulating film between the floating electrode and the N-type drift region is T₂, and a thickness of the fourth insulating film between the gate electrode and the P-type channel region is T₃, a relationship of T₁>T₂>T₃ is satisfied.

10. The method of manufacturing a semiconductor device according to claim 9,
wherein the floating electrode is provided around the field plate electrode.

11. The method of manufacturing a semiconductor according to claim 10,
wherein the field plate electrode penetrates the floating electrode and is adjacent to the gate electrode.

12. The method of manufacturing a semiconductor device according to claim 9,
wherein the first to fourth insulating films contain silicon oxide.

13. The method of manufacturing a semiconductor device according to claim 9,
wherein the first to fourth insulating films contain silicon nitride.

14. The method of manufacturing a semiconductor device according to claim 9,
wherein the floating electrode is divided into a plurality of floating electrodes, and at least one of the plurality of floating electrodes satisfies a relationship of T₁>T₂>T₃, where T₂ is a thickness of the insulating film between the one floating electrode and the N-type drift region.

15. The method of manufacturing a semiconductor device according to claim 9,
wherein the gate electrode, the floating electrode, and the field plate electrode contain N-type polysilicon.

16. The method of manufacturing a semiconductor device according to claim 9,
wherein the gate electrode, the floating electrode, and the field plate electrode contain P-type polysilicon or a metal material.
